(19) United States
(12) Patent Application Publication
(10) Pub. No.: US 2025/0357192 A1
(43) Pub. Date: Nov. 20, 2025

(54) INTERCONNECT STRUCTURE WITH LOW CAPACITANCE AND HIGH THERMAL CONDUCTIVITY

(71) Applicant: Taiwan Semiconductor Manufacturing Company, Ltd., Hsin-Chu (TW)

(72) Inventors: Shao-Kuan Lee, Kaohsiung City (TW); Ting-Ya Lo, Hsinchu (TW); Hsin-Yen Huang, New Taipei City (TW); Chia Chen Lee, Taipei City (TW); Hsiao-Kang Chang, Hsinchu City (TW)

(21) Appl. No.: 19/279,857

(22) Filed: Jul. 24, 2025

Related U.S. Application Data
(63) Continuation of application No. 18/430,150, filed on Feb. 1, 2024.
(60) Provisional application No. 63/588,781, filed on Oct. 9, 2023.

(51) Int. Cl. H01L 21/768; H01L 23/522; H01L 23/532

(52) U.S. Cl. CPC H01L 21/7682; H01L 21/76802; H01L 21/76831; H01L 21/76832; H01L 23/5226; H01L 23/53295; H01L 21/76843; H01L 21/76844

(57) ABSTRACT

Semiconductor structures and methods of forming the same are provided. An exemplary method incudes forming a first dielectric layer over a first conductive feature, forming a conductive via extending through the first dielectric layer and coupled to the first conductive feature, forming a hard mask layer over the conductive via, patterning the hard mask layer to form a first opening exposing the first dielectric layer; forming a sacrificial layer to partially fill the first opening, forming a porous dielectric layer on the sacrificial layer, after the forming of the porous dielectric layer, selectively removing the sacrificial layer to form an air gap, forming a second dielectric layer over the porous dielectric layer, and replacing a portion of the patterned hard mask layer disposed directly over the conductive via with a second conductive feature.

### PRIORITY DATA

The present application is a continuation application of U.S. patent application Ser. No. 18/430,150, filed Feb. 1, 2024, which claims the benefit of U.S. Provisional Application No. 63/588,781, filed Oct. 9, 2023, each of which is herein incorporated by reference in its entirety.

### BACKGROUND

The electronics industry has experienced an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). Thus far these goals have been achieved in large part by scaling down semiconductor IC dimensions (e.g., minimum feature size) and thereby improving production efficiency and lowering associated costs. However, such scaling has also introduced increased complexity to the semiconductor manufacturing process. Thus, the realization of continued advances in semiconductor ICs and devices calls for similar advances in semiconductor manufacturing processes and technology.

As device dimensions continue to shrink, performance of back-end-of-line (BEOL) interconnect structures are subject to higher requirements. In some examples, high parasitic capacitance may lead to lower device speed (e.g., RC delays) when distance between two adjacent conductive features reduces to meet design requirements of smaller technology nodes. Low dielectric constant (low-k) materials have been incorporated into interconnect structures to lower capacitance. While the low-k materials serve their purposes of lowering capacitance, their lackluster thermal conductivities present challenges in dissipation of heat from front-end-of-line (FEOL) devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a fragmentary cross-sectional view of an exemplary semiconductor structure, according to one or more aspects of the present disclosure.

FIG. 2 is a flowchart of a method for forming interconnect layers of the semiconductor structure, according to one or more aspects of the present disclosure.

FIGS. 3, 4, 5, 6, 7, 8, 9, 10, 11, 12, 13 and 14 are fragmentary cross-sectional views of a workpiece at various stages of fabrication according to the method in FIG. 2, according to one or more aspects of the present disclosure.

FIG. 15 is a fragmentary top view of the workpiece shown in FIG. 14, according to one or more aspects of the present disclosure.

FIG. 16 is a fragmentary cross-sectional view of a first alternative workpiece, according to one or more aspects of the present disclosure.

FIGS. 17, 18, 19, and 20 are fragmentary cross-sectional views of a second alternative workpiece at various stages of fabrication according to the method in FIG. 2, according to one or more aspects of the present disclosure.

FIG. 21 is a flowchart of another method for forming interconnect layers of the semiconductor structure, according to one or more aspects of the present disclosure.

FIGS. 22, 23, 24, 25, 26, 27, 28, 29, 30 and 31 are fragmentary cross-sectional views of a third workpiece at various stages of fabrication according to the method in FIG. 21, according to one or more aspects of the present disclosure.

FIG. 32 is a fragmentary cross-sectional view of a fourth alternative workpiece, according to one or more aspects of the present disclosure.

FIG. 33 is a fragmentary cross-sectional view of a fifth alternative workpiece, according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Source/drain region(s) may refer to a source or a drain, individually or collectively, dependent upon the context.

As the front-end-of-line (FEOL) devices becomes smaller, the back-end-of-line (BEOL) interconnect structures play a greater role in keeping up with the power, performance and area requirements. The BEOL interconnect structures may include low-k dielectric material to keep the parasitic capacitance low. In general, low-k dielectric materials possess thermal conductivities lower than those of high-k dielectric materials, metals or semiconductor materials. The low thermal conductivities of low-k dielectric materials prevent them from effectively dissipate heat generated by the FEOL devices. In addition, packing all conductive features on one side of a substrate is becoming more and more challenging. To ease the packing density, routing features may be partially moved to a backside of the substrate. Such routing features may include backside super power Rails (SPRs) and/or backside contacts. Introducing SPRs further aggravates thermal aggregation due to an increased distance between devices and a heat sink. The industry scrambles to find a solution to achieve high thermal conductivity while keeping a low parasitic capacitance.

The present disclosure provides methods of forming a dielectric structure disposed between two adjacent conductive features for heat dissipation and capacitance reduction. In an example process, a via is formed in a low-k dielectric layer, and a hard mark layer is formed over the low-k dielectric layer and patterned to form openings. A sacrificial polymer layer is then deposited to fill lower portions of the openings. A sustaining layer is deposited on the sacrificial polymer layer, and a high-kappa dielectric material layer may be formed on the sustaining layer to fill upper portions of the openings. After forming the sustaining layer, a thermal treatment is performed to selectively remove the sacrificial polymer layer, thereby forming air gaps between pieces of the pattered hard mask layer. The patterned hard mask layer may be replaced by metal lines. The high-kappa dielectric material layer, which are formed of materials with good thermal conductivities, facilitate heat dissipation. The air gaps between conductive features help keep a low capacitance.

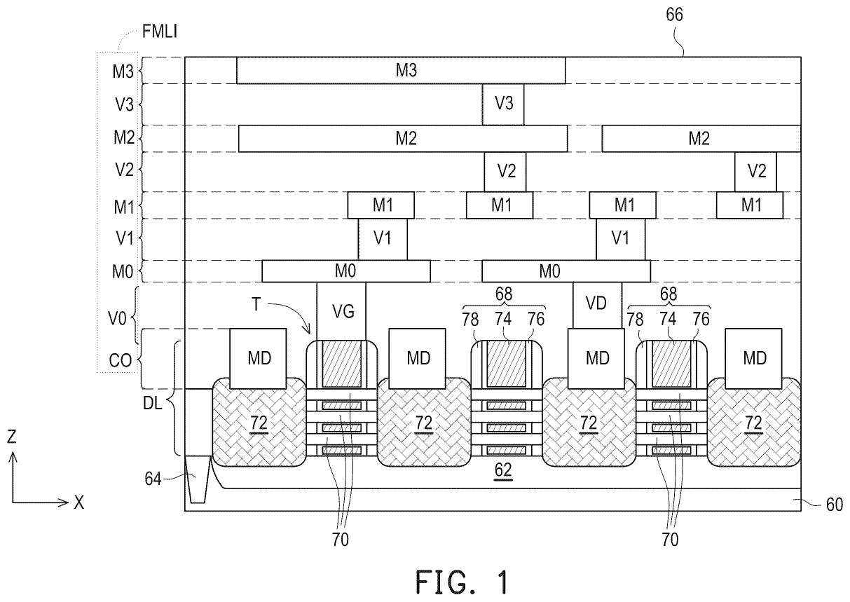

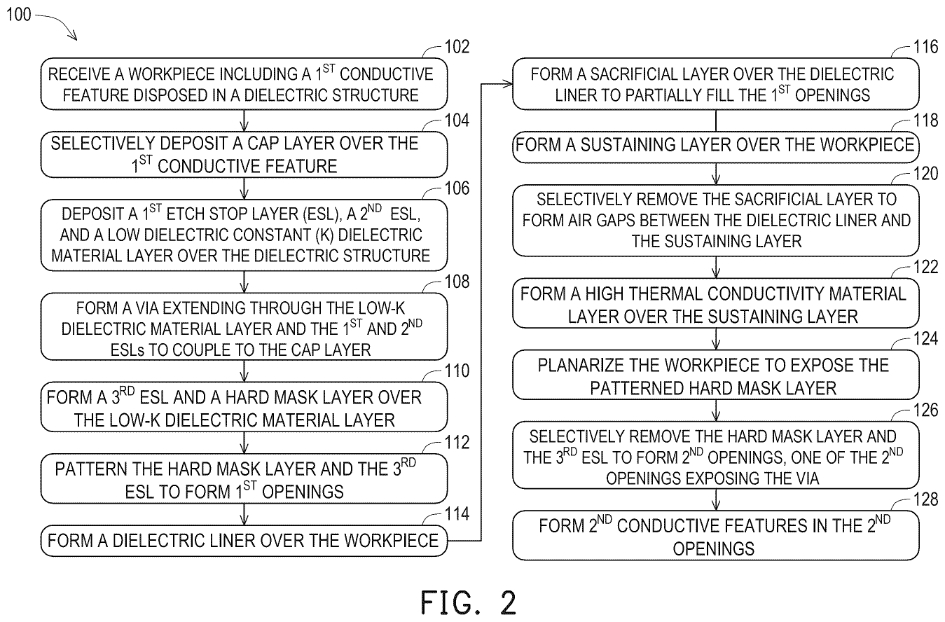

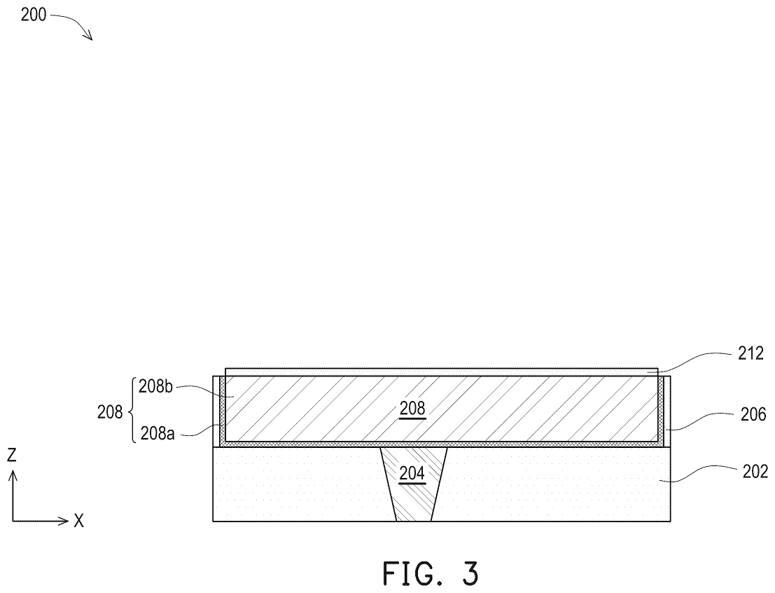

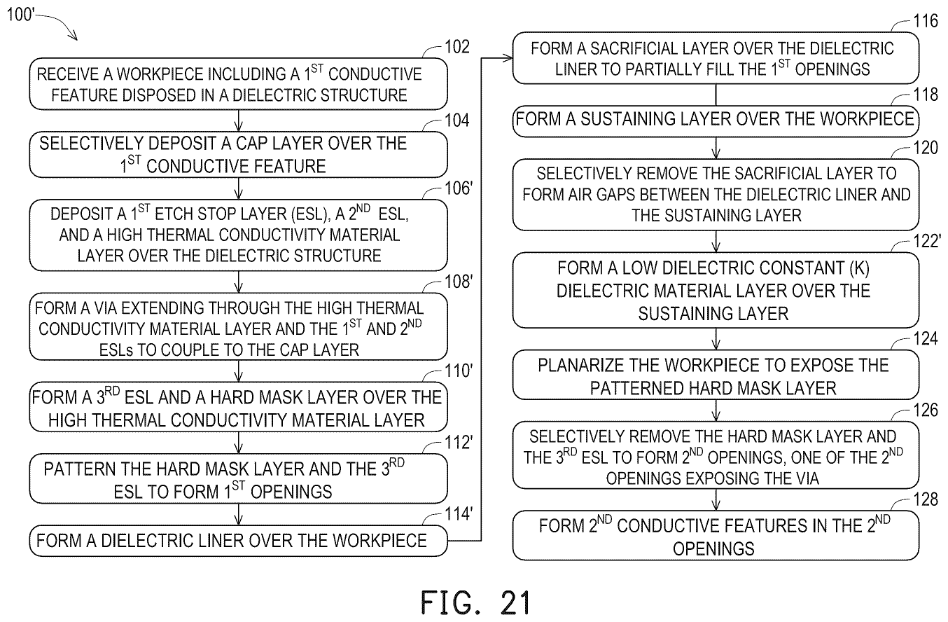

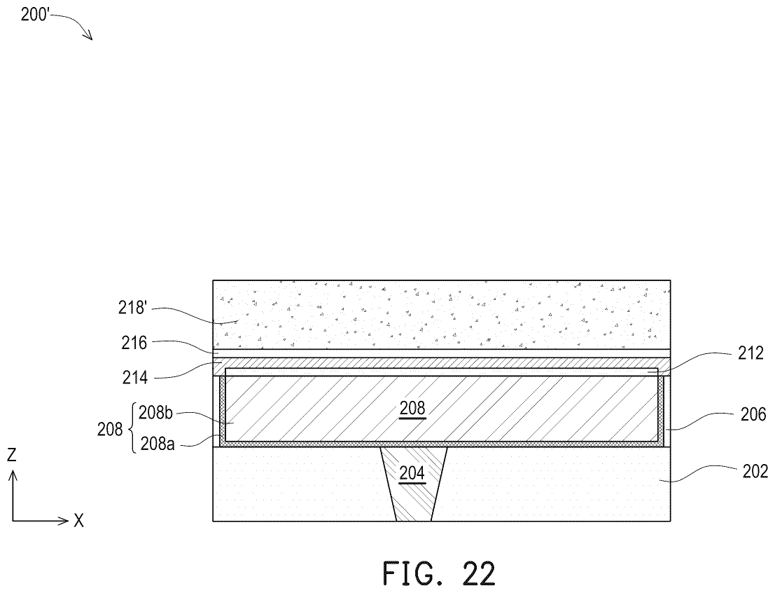

The various aspects of the present disclosure will now be described in more detail with reference to the figures. In that regard, FIG. 1 is a fragmentary cross-sectional view of an exemplary semiconductor structure, according to one or more aspects of the present disclosure. FIGS. 2 and 21 are flowcharts illustrating method 100 and method 100′ for forming interconnect layers of the semiconductor structure, according to one or more aspects of the present disclosure. Methods 100 and 100′ are merely examples and are not intended to limit the present disclosure to what is explicitly illustrated in method 100 or method 100′. Additional steps may be provided before, during and after method 100 or method 100′, and some steps described can be replaced, eliminated, or moved around for additional embodiments of the method 100 or method 100′. Not all steps are described herein in detail for reasons of simplicity. Method 100 is described below in conjunction with FIGS. 3-20, which are fragmentary top or cross-sectional views of a workpiece 200 at different stages of fabrication according to embodiments of method 100. Method 100′ is described below in conjunction with FIGS. 22-33, which are fragmentary cross-sectional views of a workpiece 200′ at different stages of fabrication according to embodiments of method 100′. Because the workpiece 200/200′ will be fabricated into a semiconductor structure upon conclusion of the fabrication processes, the workpiece 200/200′ may be referred to as a semiconductor structure 200/200′ as the context requires. Additionally, throughout the present application and across different embodiments, like reference numerals denote like features with similar structures and compositions, unless otherwise excepted. Source/drain region(s) may refer to a source or a drain, individually or collectively, dependent upon the context.

FIG. 1 is a fragmentary diagrammatic cross-sectional view of various layers (levels) that can be fabricated over a semiconductor substrate (or wafer) 60 to form a portion of a semiconductor structure, according to various aspects of the present disclosure. As represented in FIG. 1, the various layers include a device layer DL and a frontside multilayer interconnect structure FMLI disposed over the device layer DL. In various embodiments, the structure may also include a backside multilayer interconnect structure BMLI disposed under the device layer DL. The backside multilayer interconnect structure BMLI may be similar to the frontside multilayer interconnect structure FMLI.

Device layer DL includes devices (e.g., transistors, resistors, capacitors, and/or inductors) and/or device components (e.g., doped wells, gate structures, and/or source/drain features). In embodiments represented by FIG. 1, the device layer DL includes substrate 60, doped regions 62 (e.g., n-wells and/or p-wells) disposed in substrate 60, isolation feature 64, and transistors T. In the depicted embodiment, transistors T include suspended channel layers 70 and gate structures 68 disposed between source/drain features 72, where gate structures 68 wrap and/or surround suspended channel layers 70. Each gate structure 68 has a metal gate stack formed from a gate electrode 74 disposed over a gate dielectric layer 76 and gate spacers 78 disposed along sidewalls of the metal gate stack.

Multilayer interconnect structures FMLI and BMLI electrically couple various devices and/or components of device layer DL, such that the various devices and/or components can operate as specified by design requirements. Each of the multilayer interconnect structures FMLI and BMLI may include one or more interconnect layers. In the depicted embodiment, the frontside multilayer interconnect structure FMLI includes a contact interconnect layer (CO level), a via zero interconnect layer (V0 level), a metal zero interconnect layer (M0 level), a via one interconnect layer (V1 level), a metal one interconnect layer (M1 level), a via two interconnect layer (V2 level), a metal two interconnect layer (M2 level), a via three interconnect layer (V3 level), and a metal three interconnect layer (M3 level). Each of the CO level, V0 level, M0 level, V1 level, M1 level, V2 Level, M2 level, V3 level, and M3 level may be referred to as a metal level. Metal lines formed at the M0 level may be referred to as M0 metal lines. Similarly, via or metal lines formed at the V1 level, M1 level, V2 level, M2 level, V3 level, and M3 level may be referred to as V1 vias, M1 metal lines, V2 vias, M2 metal lines, V3 vias, and M3 metal lines, respectively. The present disclosure contemplates multilayer interconnect structure FMLI having more or less interconnect layers and/or levels, for example, a total number of N interconnect layers (levels) of the frontside multilayer interconnect structure FMLI with N as an integer ranging from 1 to 10. Each level of the frontside multilayer interconnect structure FMLI includes conductive features (e.g., metal lines, metal vias, and/or metal contacts) disposed in one or more dielectric layers (e.g., an interlayer dielectric (ILD) layer and an etch stop layer (ESL)). The dielectric layers of the frontside multilayer interconnect structure FMLI are collectively referred to as a dielectric structure 66. In some embodiments, conductive features at a same level of multilayer interconnect structure FMLI, such as M0 level, are formed simultaneously. In some embodiments, conductive features at a same level of multilayer interconnect structure FMLI have top surfaces that are substantially planar with one another and/or bottom surfaces that are substantially planar with one another.

In embodiments represented by FIG. 1, the CO level includes source/drain contacts MD disposed in the dielectric structure 66. The source/drain contacts MD may be formed on and in direct contact with silicide layers disposed directly on the source/drain features 72. The V0 level includes gate vias VG disposed on the gate structures 68 and source/drain contact vias VD disposed on the source/drain contacts MD, where gate vias VG connect gate structures 68 to M0 metal lines, source/drain vias V0 connect source/drain contacts MD to M0 metal lines. In some embodiments, the V0 level may also include butted contacts disposed in the dielectric structure 66. The V1 level includes V1 vias disposed in the dielectric structure 66, where V1 vias connect M0 metal lines to M1 metal lines. M1 level includes M1 metal lines disposed in the dielectric structure 66. V2 level includes V2 vias disposed in the dielectric structure 66, where V2 vias connect M1 metal lines to M2 metal lines. M2 level includes M2 metal lines disposed in the dielectric structure 66. V3 level includes V3 vias disposed in the dielectric structure 66, where V3 vias connect M2 metal lines to M3 metal lines. FIG. 1 has been simplified for the sake of clarity to better understand the inventive concepts of the present disclosure.

Referring to FIGS. 2 and 3, method 100 includes a block 102 where a workpiece 200 is received. The workpiece 200 includes a dielectric layer 202. The dielectric layer 202 may include a low dielectric constant (low-k) dielectric material that has a dielectric constant smaller than that of silicon oxide, which is about 3.9. For example, the dielectric layer 202 may include a porous organosilicate thin film (e.g., SiOCH), tetraethylorthosilicate (TEOS) oxide, un-doped silicate glass, borophosphosilicate glass (BPSG), fluorosilicate glass (FSG), phosphosilicate glass (PSG), fluorine-doped silicon dioxide, carbon-doped silicon dioxide, porous silicon dioxide, porous carbon-doped silicon dioxide, silicon oxycarbonitride (SiOCN), boron carbonitride, spin-on silicon based polymeric dielectrics, or combinations thereof. In some instances, the dielectric layer 202 may be referred to as an interlayer dielectric (ILD) layer or an intermetal dielectric (IMD) layer.

The workpiece 200 also includes a conductive feature (e.g., via) 204 extending through the dielectric layer 202. The conductive feature may include copper (Cu), nickel (Ni), cobalt (Co), ruthenium (Ru), iridium (Ir), aluminum (Al), platinum (Pt), palladium (Pd), gold (Au), silver (Ag), osmium (Os), tungsten (W), or molybdenum (Mo), or a combination thereof. In various embodiments, the conductive feature 204 may be one of the vias (e.g., the gate via VG, source/drain contact via VD, V1 via, V2 via) of the frontside multilayer interconnect structure FMLI. In an embodiment, the conductive feature 204 is a source/drain contact via VD.

The workpiece 200 also includes a dielectric structure 206 disposed on the dielectric layer 202. In an embodiment, the dielectric structure 206 is a single-layer structure and is formed of a dielectric material layer that may include a low dielectric constant (low-k) dielectric material having a dielectric constant smaller than that of silicon oxide, which is about 3.9. For example, the dielectric material layer may include a porous organosilicate thin film (e.g., SiOCH), tetraethylorthosilicate (TEOS) oxide, un-doped silicate glass, borophosphosilicate glass (BPSG), fluorosilicate glass (FSG), phosphosilicate glass (PSG), fluorine-doped silicon dioxide, carbon-doped silicon dioxide, porous silicon dioxide, porous carbon-doped silicon dioxide, silicon oxycarbonitride (SiOCN), boron carbonitride, spin-on silicon based polymeric dielectrics, or combinations thereof. In some other embodiments, the dielectric structure 206 may be a dual-layer structure that includes the dielectric material layer formed over an etch stop layer (ESL). In some embodiments, the ESL includes aluminum oxide, aluminum nitride, silicon nitride, silicon oxycarbide, silicon carbonitride, or a combination thereof.

The workpiece 200 also includes a first conductive feature 208 extending through the dielectric structure 206 and in direct contact with the conductive feature 204. The first conductive feature 208 includes a barrier layer 208a extending along bottom and sidewall surfaces of a metal fill layer 208b. The barrier layer 208a may include titanium nitride (TiN), cobalt nitride (CON), manganese nitride (MnN), nickel nitride (NiN), tungsten nitride (WN), or tantalum nitride (TaN). The metal fill layer 208b may include copper (Cu), nickel (Ni), cobalt (Co), ruthenium (Ru), iridium (Ir), aluminum (Al), platinum (Pt), palladium (Pd), gold (Au), silver (Ag), osmium (Os), tungsten (W), or molybdenum (Mo), or combinations thereof. In this illustrated example, the workpiece 200 is a representative of a portion of two immediately adjacent interconnect layers (e.g., the CO level and the M0 level) of the frontside multilayer interconnect structure FMLI. In an embodiment, the first conductive feature 208 represents one of the M0 metal lines and the conductive feature 204 represents one of the V0 vias. In other embodiments, the first conductive feature 208 represents one of the M1 metal lines, and the conductive feature 204 represents one of the V1 vias.

Still referring to FIGS. 2 and 3, method 100 includes a block 104 where a cap layer 212 is selectively deposited over the first conductive feature 208. The cap layer 212 may also be referred to as a metal cap 212 or a conductive cap layer 212 and is formed from a metal different from the metal that forms the barrier layer 208a and the metal fill layer 208b. In embodiments where the metal fill layer 208b is formed of copper, the cap layer 212 may include titanium (Ti), tantalum (Ta), molybdenum (Mo), nickel (Ni), cobalt (Co), ruthenium (Ru), or tungsten (W). In an embodiment, the cap layer 212 includes cobalt (Co). In some implementations, at block 104, the cap layer 212 is selectively deposited on top surfaces of the first conductive feature 208 by metal organic chemical vapor deposition (MOCVD) using metalorganic precursors each having a metal ion and coordinating ligands. As shown in FIG. 3, due to the selective nature of formation, the cap layer 212 is only deposited on top surface of the metal fill layer 208b and is absent from the surfaces of the dielectric structure 206 and the barrier layer 208a. The cap layer 212 suppresses electromigration or hillock formation of the metal fill layer 208b. Besides serving to reduce electromigration, the cap layer 212 may also repair damages done to the metal fill layer 208b during a planarization process. In some other embodiments, the cap layer 212 may be deposited on top surfaces of the metal fill layer 208b and the barrier layer 208a and is absent from the surface of the dielectric structure 206.

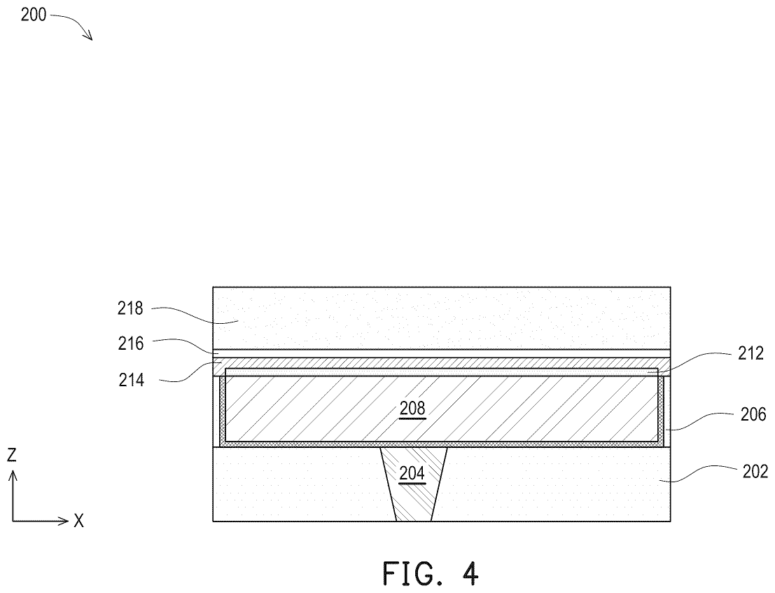

Referring to FIGS. 2 and 4, method 100 includes a block 106 where a first etch stop layer (ESL) 214, a second ESL 216, and a low dielectric constant (or low-k) dielectric material layer 218 are formed over the dielectric structure 206. In some embodiments, the first and second ESLs may include aluminum oxide, aluminum nitride, silicon nitride, silicon oxycarbide, silicon carbonitride, or a combination thereof and may be deposited using atomic layer deposition (ALD), physical vapor deposition (PVD), chemical vapor deposition (CVD), or plasma enhanced CVD (PECVD). In an example process, the first ESL 214 is conformally disposed over the workpiece 200, including on top and sidewall surfaces of the cap layer 212, the second ESL 216 is then conformally disposed over the first ESL 214. After forming the second ESL 216, the low-k dielectric material layer 218 is formed. The low-k dielectric material layer 218 has a dielectric constant smaller than that of silicon oxide, which is about 3.9. For example, the low-k dielectric material layer 218 may include a porous organosilicate thin film (e.g., SiCOH), tetraethylorthosilicate (TEOS) oxide, un-doped silicate glass, borophosphosilicate glass (BPSG), fluorosilicate glass (FSG), phosphosilicate glass (PSG), fluorine-doped silicon dioxide, carbon-doped silicon dioxide, porous silicon dioxide, porous carbon-doped silicon dioxide, silicon oxycarbonitride (SiOCN), boron carbonitride, spin-on silicon based polymeric dielectrics, or combinations thereof. In some other embodiments, instead of forming the two ESLs 214 and 216, a single-layer ESL is disposed between the low-k dielectric material layer 218 and the dielectric structure 206.

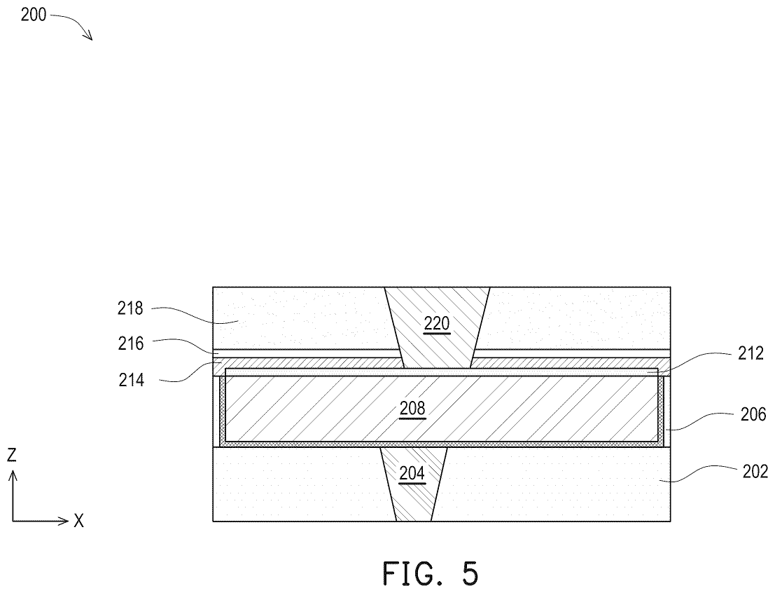

Referring to FIGS. 2 and 5, method 100 includes a block 108 where a via 220 is formed to extend through the low-k dielectric material layer 218 and the first and second ESLs 214 and 216 to couple to the cap layer 212. In an example process, the low-k dielectric material layer 218 and the first and second ESLs 214 and 216 are patterned to form a via opening (now filled by the via 220) exposing the cap layer 212. The patterning of the low-k dielectric material layer 218 and the first and second ESLs 214 and 216 may include photolithography processes and etching processes, such as deposition of a photoresist layer, photolithographic patterning of the photoresist layer, etching of the low-k dielectric material layer 218 and the first and second ESLs 214 and 216 using the patterned photoresist layer as an etch mask, and selective removal of the photoresist layer. The photoresist layer may include hydrocarbons and may be deposited using spin-on coating. The etching of the low-k dielectric material layer 218 and the first and second ESLs 214 and 216 may include dry etching, wet etching, reactive ion etching (RIE), and/or other suitable processes. After forming the via opening, the photoresist layer may be removed by ashing or selective etching. A metal layer is then deposited over the workpiece 200, including in the via opening. In some embodiments, the metal layer (and the via 220 formed therefrom) includes ruthenium (Ru), tungsten (W), molybdenum (Mo), combinations thereof, or other suitable conductive materials that are less prone to diffusion issues. The metal layer may be deposited using ALD, CVD, plasma enhanced ALD (PEALD), PECVD, electroplating, or electroless deposition. After deposition of the metal layer, a planarization process, such as a chemical mechanical polishing (CMP) process, is performed to remove excess metal layer to expose the top surface of the low-k dielectric material layer 218. After the planarization process, the via 220 is formed in the via opening. To reduce a parasitic resistance, the via 220 is formed of metal and does not include a barrier layer that is similar to the barrier layer 208a. Forming a barrier-free via 220 advantageously reduces parasitic resistance (e.g., contact resistance) of the workpiece 200.

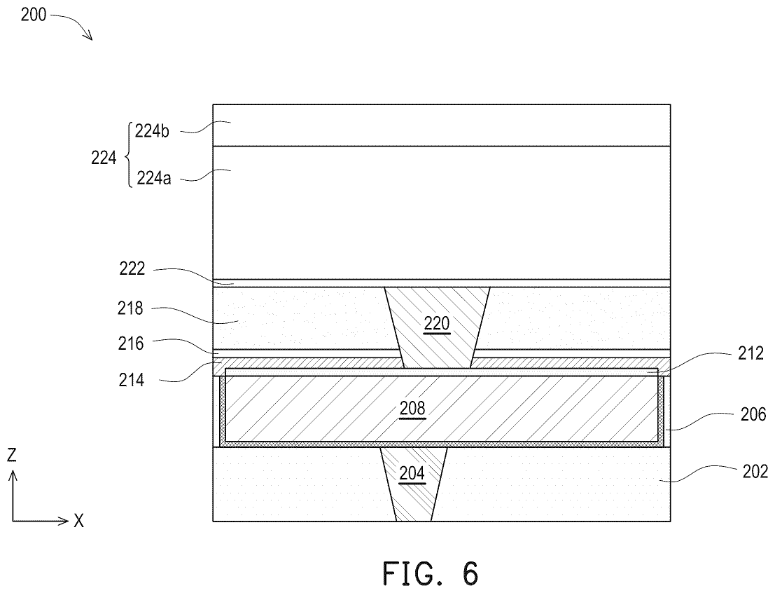

Referring to FIGS. 2 and 6, method 100 includes a block 110 where a third ESL 222 and a hard mask 224 are formed over the low-k dielectric material layer 218. After forming the via 220, the third ESL 222 and the hard mask 224 are deposited over the workpiece 200. The third ESL 222 may be similar to the one of the first and second ESLs 214 and 216. The hard mask 224 may be deposited on the third ESL 222 using ALD, CVD, PEALD, or PECVD. In this illustrated example, the hard mask 224 is a dual-layer structure and includes a first layer 224a and a second layer 224b formed on the first layer 224a. The first layer 224a and the second layer 224b have different compositions and may be formed of aluminum oxide, silicon oxide, silicon nitride, silicon carbonitride, silicon oxycarbide, silicon oxynitride, silicon oxycarbonitride, other suitable materials, or combinations thereof.

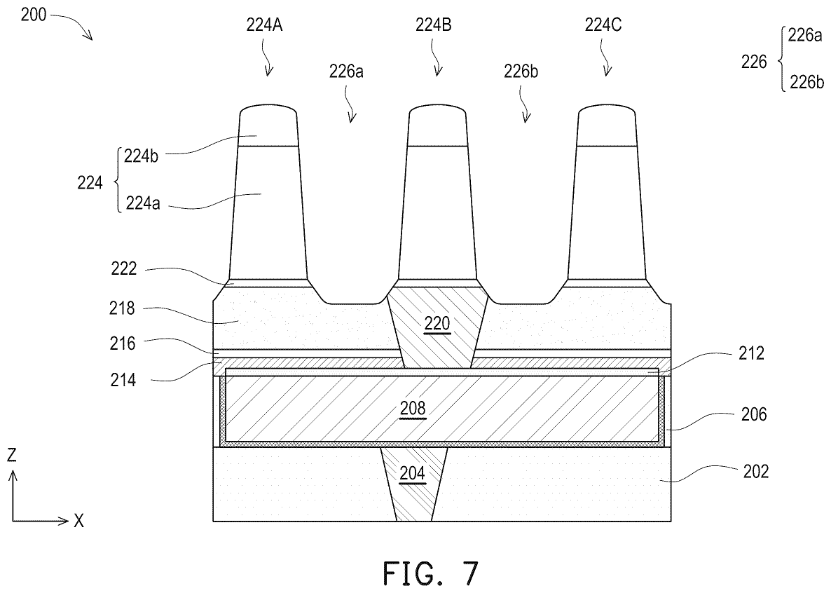

Referring to FIGS. 2 and 7, method 100 includes a block 112 where the hard mask 224 and the third ESL 222 are patterned to form one or more openings (e.g., openings 226a and 226b). The patterning of the hard mask 224 and the third ESL 222 may include photolithography processes and etching processes. In the depicted embodiment, operations in block 112 include deposition of a photoresist layer (not shown), photolithographic patterning of the photoresist layer, etching of the hard mask 224 and the third ESL 222 using the patterned photoresist layer as an etch mask to form openings, and selective removal of the photoresist layer after forming of the openings. In this depicted example, the patterning of the hard mask 224 and the third ESL 222 forms the openings 226a and 226b, and the patterned hard mask 224 includes three pieces 224A, 224B, and 224C separated by the two openings 226a and 226b. In the present embodiments, since the dielectric material layer 218 is a low-k dielectric material layer, the etchant(s) used during the patterning of the hard mask 224 and the third ESL 222 may also slightly etch the low-k dielectric material layer 218. As a result, the openings (e.g., openings 226a and 226b) extend into the low-k dielectric material layer 218. The openings 226a and 226b may be individually or collectively referred to as opening(s) 226.

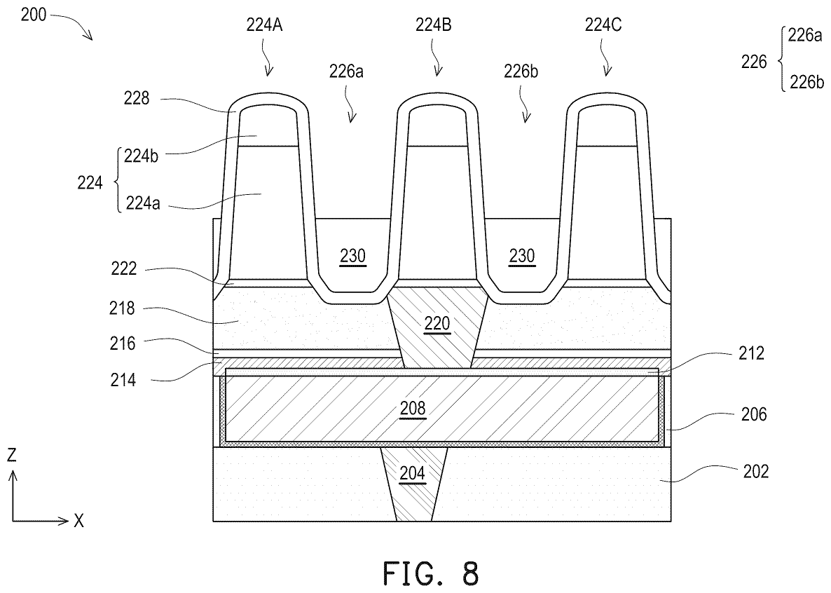

Referring to FIGS. 2 and 8, method 100 includes a block 114 where a dielectric liner 228 is formed over the workpiece 200. In an embodiment, the dielectric liner 228 is conformally deposited over the workpiece 200, including in the two openings 226a and 226b, using ALD, CVD, plasma enhanced CVD (PECVD), plasma enhanced ALD (PEALD), or other suitable methods. The term “conformally” may be used herein for ease of description of a layer having substantially uniform thickness over various regions. A deposition thickness of the dielectric liner 228 may be between about 15 Å and about 35 Å.

In an embodiment, the dielectric liner 228 is formed of a material having a dielectric constant ranging from 3.5 to 5 and having a thermal conductivity (kappa) less than 5 W/mK. For example, the dielectric liner 228 includes silicon oxycarbonitride. In another alternative embodiment, the dielectric liner 228 is formed of a material having a thermal conductivity (kappa) greater than 5 W/mK. For example, the dielectric liner includes boron nitride with a thermal conductivity ranging from 5 to 400 W/mK. In the present disclosure, a dielectric material having a thermal conductivity that is less than 5 W/mK may be referred to as a low-kappa dielectric material, and a dielectric material having a thermal conductivity no less than 5 W/mK may be referred to as a high-kappa dielectric material.

Still referring to FIGS. 2 and 8, method 100 includes a block 116 where a sacrificial layer 230 is formed over the dielectric liner 228 to partially fill the opening 226. In an example process, a polymer layer is deposited over the workpiece 200, including in the openings 226. The polymer layer may be deposited by using CVD, PECVD, flowable CVD (FCVD), ALD, PEALD, or spin-on coating. The deposited polymer layer may be heated to increase its flowability to have a smoother top surface. A curing process may be then performed to cure the polymer layer. In some instances, the curing process may include a bake process, an anneal process, a drying process, or an ultraviolet (UV) radiation process. The cured polymer layer is then planarized and selectively etched back, thereby forming the sacrificial layer 230 in the lower portion of the opening 226. The etch back of the polymer layer is used to define a height of the air gap 234.

While the sacrificial layer 230 will be removed in a subsequent step, it is selected such that it can withstand the planarization process and the deposition of a sustaining layer 232 (to be described below) without becoming structurally compromised. For those reasons, the sacrificial layer 230 needs to be easy to remove and yet to remain stable at about the deposition temperature of the sustaining layer. Based on these criteria, the sacrificial layer 230 may include polyvinyl alcohol (PVA), polyacrylate, polycarbonate (PC), or other suitable polymers.

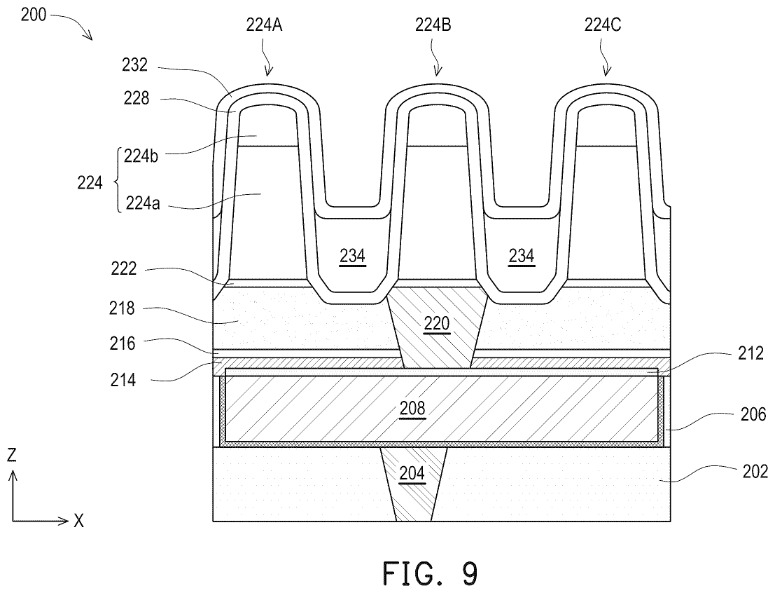

Referring to FIGS. 2 and 9, method 100 includes a block 118 where a sustaining layer 232 is formed over the workpiece 200. In embodiments represented by FIG. 9, a low-k dielectric material is conformally deposited over the workpiece 200, including on the sacrificial layer 230 and the dielectric liner 228, to form a sustaining layer 232 which has a loose structure and covers the sacrificial layer 230. In some embodiments, the sustaining layer 232 has a porous structure. The deposition for forming the sustaining layer 232 may be implemented by PECVD, PEALD, ALD, CVD, other suitable processes, or combinations thereof. In an embodiment, the sustaining layer 232 includes silicon oxide.

Still referring to FIGS. 2 and 9, method 100 includes a block 120 where the sacrificial layer 230 is selectively removed to form an air gap 234 between the dielectric liner 228 and the sustaining layer 232. In some embodiments, a thermal treatment (e.g., an anneal process, a bake process) and/or an ultraviolet process may be performed to decompose the sacrificial layer 230 into volatile compound that can be diffused through the porous structure of the sustaining layer 232. The removal of the sacrificial layer 230 forms an air gap 234. As depicted by FIG. 9, the air gap is confined by the dielectric liner 228 and the sustaining layer 232. In the illustrated example, an air gap 234 is formed between the pieces 224A and 224B of the patterned hard mask 224, and another air gap 234 is disposed between the pieces 224B and 224C of the patterned hard mask 224. Because air has a dielectric constant close to 1, the air gaps 234 lower the effective dielectric constant of the dielectric structures among the second conductive features (e.g., the second conductive features 242a-242c).

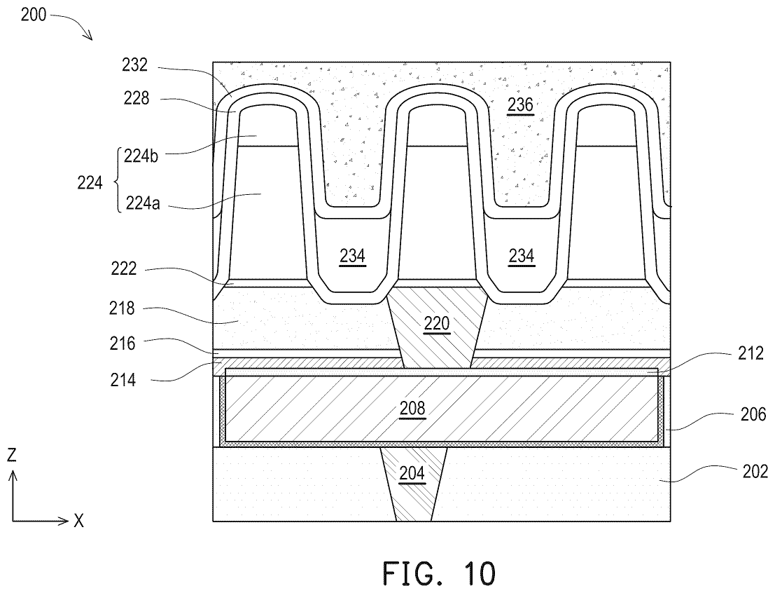

Referring to FIGS. 2 and 10, method 100 includes a block 122 where a high thermal conductivity (high-kappa) dielectric material layer 236 is formed over the sustaining layer 232 using ALD, CVD, plasma enhanced CVD (PECVD), or microwave PECVD. In some embodiments, the high-kappa dielectric material layer 236 may include diamond, diamond-like carbon, or aluminum nitride (AlN). A thermal conductivity of diamond may be in a range between about 100 W/mK and 2000 W/mK. A thermal conductivity of aluminum nitride may be in a range between about 5 W/mK and 300 W/mK. In some embodiments, the high-kappa dielectric material layer 236 may include silicon nitride having a thermal conductivity greater than 5 W/mK. In an embodiment, the high-kappa dielectric material layer 236 includes diamond or diamond-like carbon. For embodiments in which the high-kappa dielectric material layer 236 has a porous structure, the sacrificial layer 230 may be selectively removed after forming the high-kappa dielectric material layer 236.

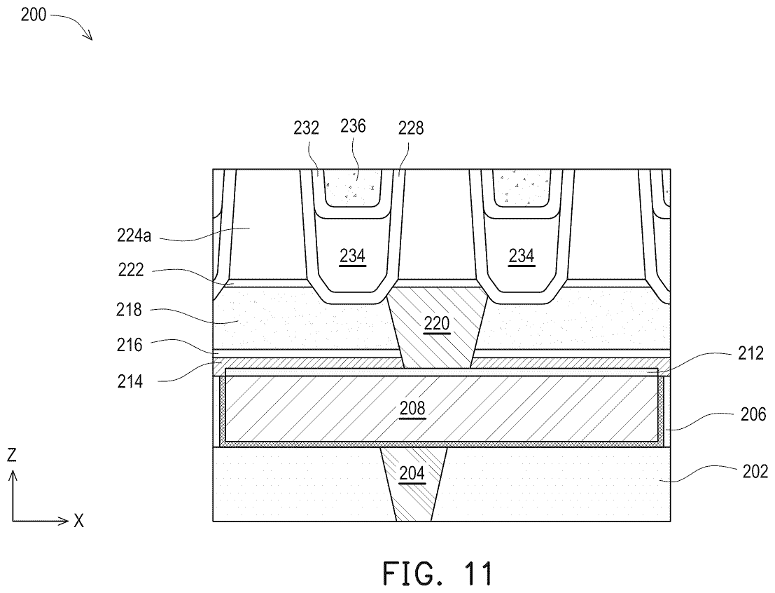

Referring to FIGS. 2 and 11, method 100 includes a block 124 where the workpiece 200 is planarized to expose the patterned hard mask 224. After forming the high-kappa dielectric material layer 236, a planarization process is performed to the workpiece 200. In an embodiment, the planarization process stops after exposing the top surface of the first layer 224a of the hard mask 224. Upon completion of the planarization process, a topmost surface of the sustaining layer 232, a topmost surface of the dielectric liner 228, and a top surface of the high-kappa dielectric material layer 236 are coplanar. The sustaining layer 232 extends along bottom and sidewall surfaces of the high-kappa dielectric material layer 236 and is in direct contact with the dielectric liner 228.

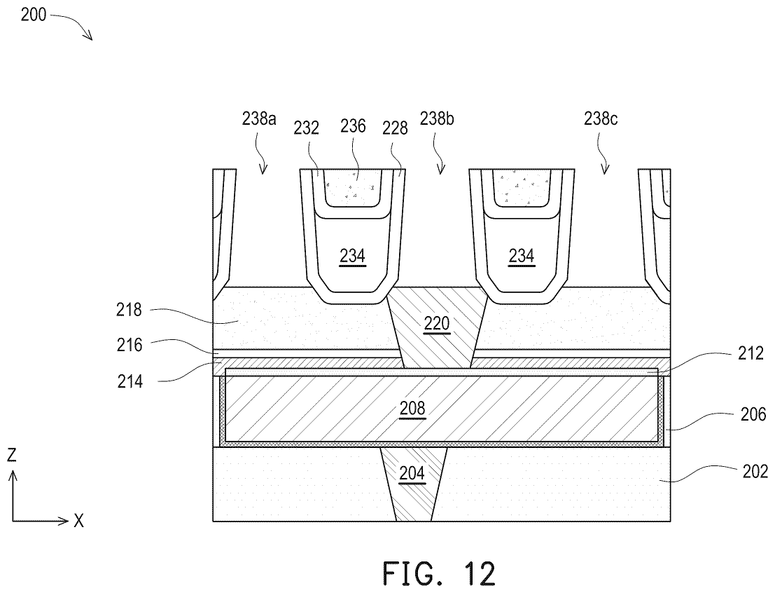

Referring to FIGS. 2 and 12, method 100 includes a block 126 where the patterned hard mask 224 and the third ESL 222 are selectively removed to form openings 238a-238c. After performing the planarization process to expose the top surface of the first layer 224a of the hard mask 224, an etching process is performed to selectively etch the exposed first layer 224a of the hard mask 224 and the third ESL 222 thereunder without substantially etching the dielectric liner 228. In this illustrated example, the etching process removes the pieces 224A, 224B, and 224C and the third ESL 222 thereunder, thereby forming the openings 238a, 238b, and 238c, respectively. The number of openings is just an example and is not intended to be liming. The openings 238a and 238c expose top surface of the low-k dielectric material layer 218, and the opening 238b exposes top surface of the via 220.

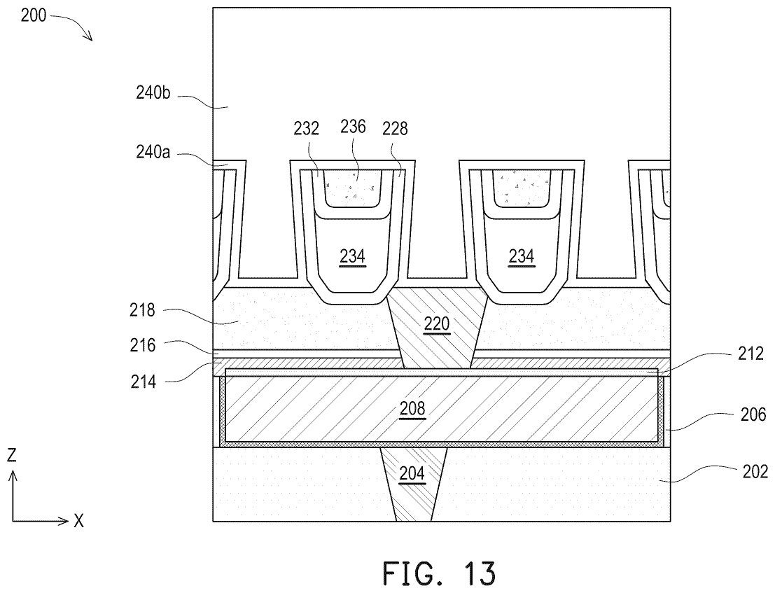

Referring to FIGS. 2 and 13, 14, 15, method 100 includes a block 128 where second conductive features 242a-242c are formed in the openings 238a-238c, respectively. With reference to FIG. 13, a conductive barrier layer 240a is conformally formed over the workpiece 200, including in the openings 238a-238c. The barrier layer 208a may include titanium nitride (TiN), cobalt nitride (CON), manganese nitride (MnN), nickel nitride (NiN), tungsten nitride (WN), or tantalum nitride (TaN) and may be formed by ALD, CVD, PEALD, PECVD, or other suitable processes. A metal fill layer 240b is then deposited over the conductive barrier layer 240a and in the openings 238a-238c. The metal fill layer 208b may include copper (Cu), nickel (Ni), cobalt (Co), ruthenium (Ru), iridium (Ir), aluminum (Al), platinum (Pt), palladium (Pd), gold (Au), silver (Ag), osmium (Os), tungsten (W), or molybdenum (Mo), or a combination thereof and may be formed by ALD, CVD, PEALD, PECVD, chemical electroplating, or other suitable processes.

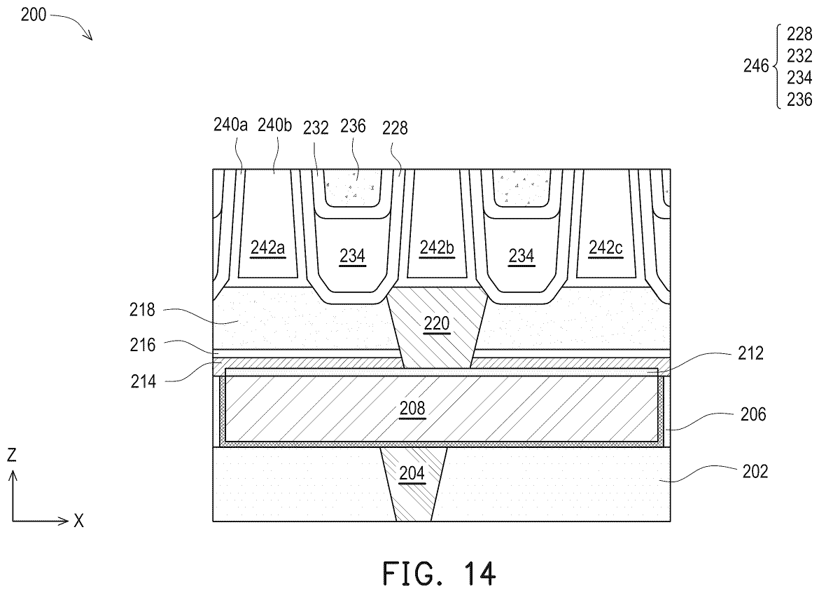

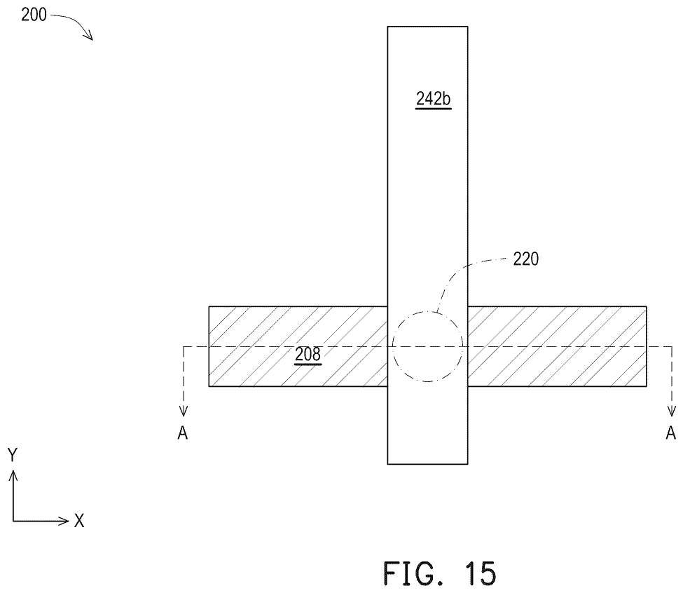

With reference to FIG. 14, after forming the metal fill layer 208b, a planarization process is performed to remove excess portions of the metal fill layer 208b and the conductive barrier layer 240b to form second conductive features 242a, 242b, and 242c in the openings 238a-238c, respectively. Top surfaces of the second conductive features 242a, 242b, and 242c are planar and coplanar with the top surface of the high-kappa dielectric material layer 236. The second conductive feature 242b is disposed over and in direct contact with the via 220. In this embodiment, the metal fill layer 240b of the second conductive feature 242b is physically isolated from the via by the conductive barrier layer 240a. The second conductive feature 242b is spaced apart from adjacent second conductive features 242a and 242c by a dielectric structure 246 which is combination of the dielectric liner 228, the sustaining layer 232, the air gap 234 confined by the dielectric liner 228 and the sustaining layer 232, and the high-kappa dielectric material layer 236 wrapped around by the sustaining layer 232. Forming the air gap 234 lowers the effective dielectric constant of the dielectric structure between two adjacent second conductive features (e.g., 242a and 242b) and thus advantageously reduce parasitic capacitance. Implementing the high-kappa dielectric material layer 236 would advantageously improve thermal dissipation, thereby improving reliability. FIG. 15 depicts a fragmentary top view of the workpiece shown in FIG. 14. More specifically, FIG. 15 illustrates the second conductive feature 242b, the via 220, and the first conductive feature 208. In this illustrated example, the first conductive feature 208 extends lengthwise along the X direction and the second conductive feature 242b extends lengthwise along the Y direction which is substantially perpendicular to the X direction. In some embodiments, the second conductive features 242a-242c may be M2 metal lines, the first conductive feature 208 may be one of the M1 metal lines, and the via 220 may be one of the V1 vias.

After forming the second conductive features 242a-242c, further processes may be performed. For example, operations 104-128 may be repeated to form interconnect layers over the second conductive features 242a-242c. Such further processes may include forming a backside multilayer interconnect structure BMLI under the device level DL.

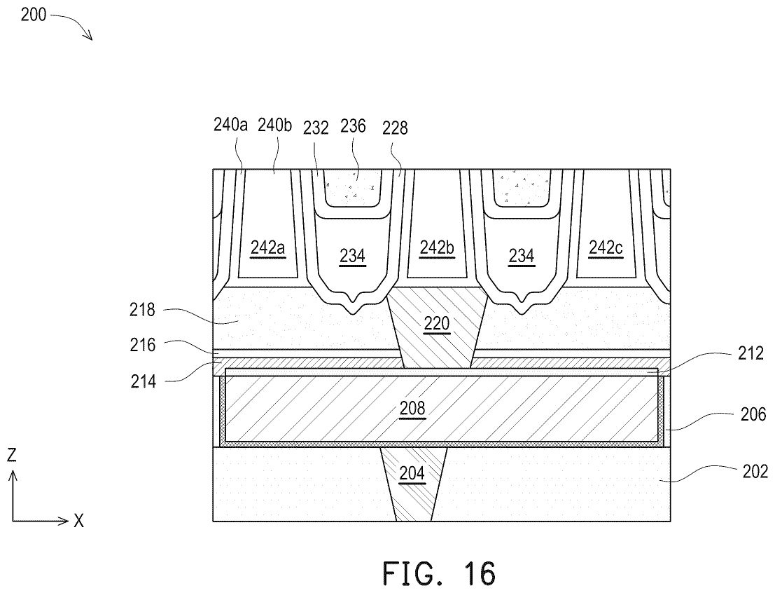

In the above embodiments, the air gap 234 and the dielectric liner 228 extend into the low-k dielectric material layer 218, and a bottommost bottom surface of the dielectric liner 228 is substantially planar. In some other embodiments, depending on the composition of the low-k dielectric material layer 218, the composition of the third ESL 222, and the etchant used in block 112 during the patterning of the hard mask 224, the opening 226 may have a different profile, and as a result, the dielectric liner 228 may have a different profile. FIG. 16 represents an alternative embodiment in which the dielectric liner 228 has a different profile than that shown in FIG. 14.

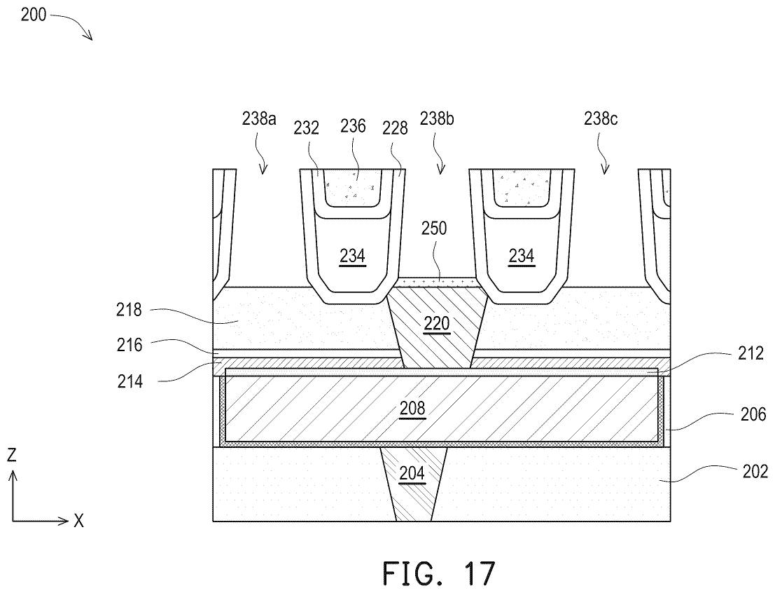

In the above embodiments, the metal fill layer 240b of the second conductive feature 242b is physically separated from the via 220 by the conductive barrier layer 240a. In an alternative embodiment, to further reduce parasitic resistance, the metal fill layer 240b of the second conductive feature 242b may be in direct contact with the via 220. FIGS. 17-20 depict fragmentary cross-sectional views of the workpiece during various fabrication steps of forming the second conductive feature 242a-242c where the metal fill layer 240b of the second conductive feature 242b is in direct contact with the via 220, according to this alternative embodiment.

With reference to FIG. 17 and FIG. 12, after forming the openings 238a-238c (shown in FIG. 12), a blocking layer 250 is selectively formed on metallic surfaces, but not on dielectric surfaces. In an embodiment, the blocking layer 250 is selectively deposited on the exposed top surface of the via 220, and the top surface of the low-k dielectric material layer 218 is free of the blocking layer 250. The blocking layer 250 may be formed by applying inhibitors using chemical vapor deposition (CVD), spin-on coating, or spray techniques. Molecules of the inhibitor may include silicon, carbon-based polymers (e.g., Benzotriazole (BTA), carbon layers, graphene, graphite), or self-aligning molecules (e.g., Octadecyl phosphonic acid, thiol).

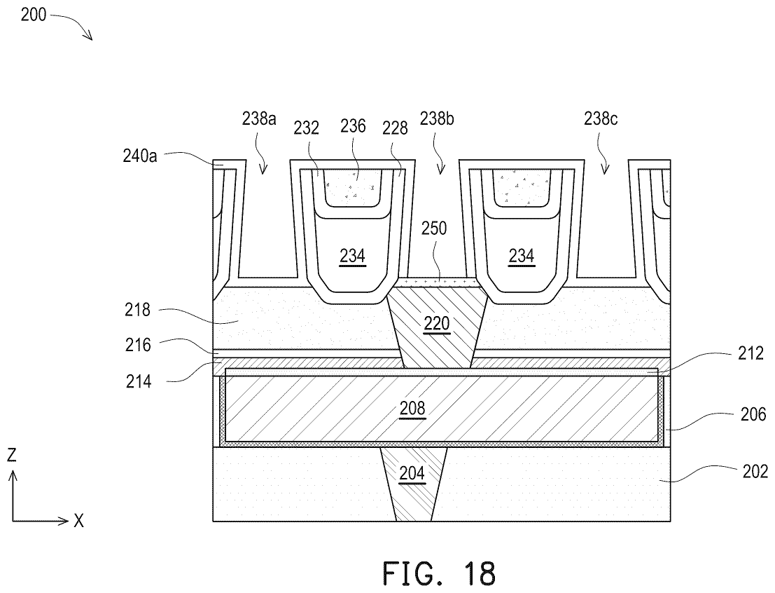

With reference to FIG. 18, after forming the blocking layer 250, the conductive barrier layer 240a is deposited over the workpiece 200. The formation and composition of the conductive barrier layer 240a have been described above with reference to FIG. 13, and repeated description is omitted for reason of simplicity. The blocking layer 250 prevents the conductive barrier layer 240a from being disposed directly thereon. That is, upon completion of the deposition of the conductive barrier layer 240a, as illustrated in FIG. 18, the opening 238b still exposes the top surface of the blocking layer 250. It is noted that, since two ends of the blocking layer 250 are disposed immediately adjacent to the dielectric liner 228, the portion of the conductive barrier layer 240a extending along sidewall surfaces of the dielectric liner 228 is in direct contact with the blocking layer 250.

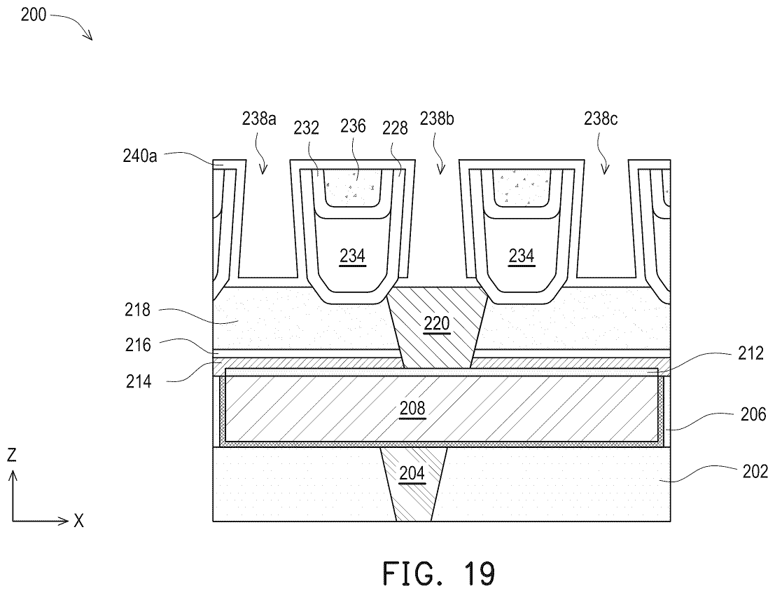

With reference to FIG. 19, after forming the conductive barrier layer 240a, the blocking layer 250 is selectively removed. The blocking layer 250 may be selectively removed by thermal, plasma treatment or wet chemical approaches. The removal of the blocking layer 250 exposes an entirety of the top surface of the via 220.

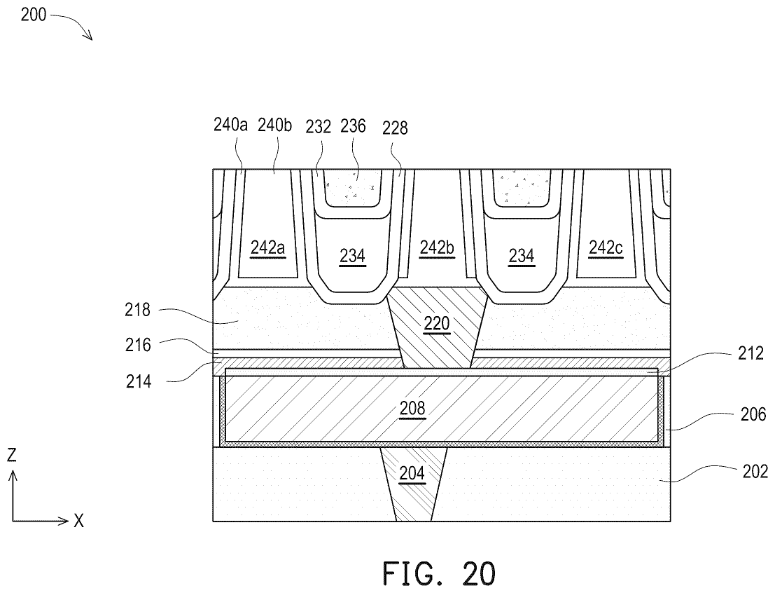

With reference to FIG. 20, the metal fill layer 240b is then deposited over the workpiece 200, including in the openings 238a-238c. A planarization process is performed to remove excess portions of the conductive barrier layer 240a and the metal fill layer 240b, thereby defining final structures of the second conductive features 242a, 242b, and 242c. In the cross-sectional view represented by FIG. 20, the metal fill layer 240b of the second conductive feature 242b is in direct contact with the via 220. A portion of the metal fill layer 240b of the second conductive feature 242b is disposed directly under the conductive barrier layer 240a. The metal fill layer 240b of the second conductive features 242a and 242c is isolated from the low-k dielectric material layer 218 by the conductive barrier layer 240a. Since there is no barrier layer disposed directly between the via 220 and the metal fill layer 240b, parasitic resistance of the workpiece 200 may be advantageously reduced.

In the above embodiments described with reference to FIGS. 2-20, method 100 includes forming the high-kappa dielectric material layer 236 over the air gap 234 to improve thermal dissipation. In an alternative method 100′ represented by FIG. 21, a high-kappa material layer may be disposed under the air gap 234 to improve thermal dissipation. For example, a high-kappa material layer may be deposited in place of the low-k dielectric material layer 218.

Referring to FIGS. 21, 2, 3, and 22, method 100′ includes the block 102 where the workpiece 200 (shown in FIG. 3) is received and the block 104 where the cap layer 212 (shown in FIG. 3) is selectively formed. For ease of description, the workpiece 200 depicted in FIG. 3 is referred to as workpiece 200′ when describing the alternative method 100′.

Still referring to FIGS. 21 and 22, method 100′ includes a block 106′ where the first etch stop layer (ESL) 214, the second ESL 216, and a high-kappa dielectric material layer 218′ are formed over the dielectric structure 206. The formations and compositions of the first and second ESLs 214 and 216 have been described above with reference to block 106 of method 100 and repeated description is omitted for brevity. The high-kappa dielectric material layer 218′ is then formed on the second ESL 216 using ALD, PEALD, CVD, plasma enhanced CVD (PECVD), or microwave PECVD. In some embodiments, the high-kappa dielectric material layer 218′ may include diamond, diamond-like carbon, or aluminum nitride (AlN). A thermal conductivity of diamond may be in a range between about 100 W/mK and 2000 W/mK. A thermal conductivity of aluminum nitride may be in a range between about 5 W/mK and 300 W/mK. In some embodiments, the high-kappa dielectric material layer 218′ may include silicon nitride having a thermal conductivity greater than 5 W/mK.

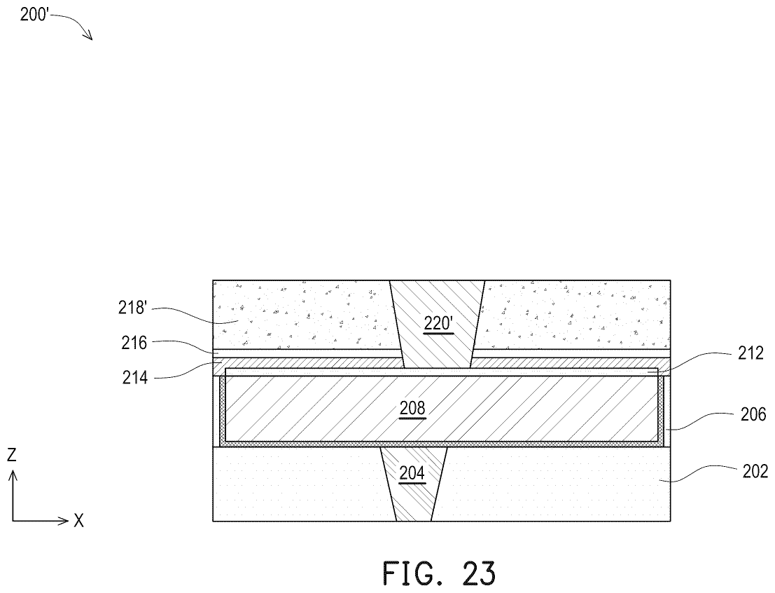

Referring to FIGS. 21 and 23, method 100′ includes a block 108′ where a via 220′ is formed to extend through the high-kappa dielectric material layer 218′ and the first and second ESLs 214 and 216 to couple to the cap layer 212. The via 220′ is substantially similar to the via 220, and operations at block 108′ are similar to those in block 108. For this reason, detailed description of operations at block 108′ is omitted for brevity.

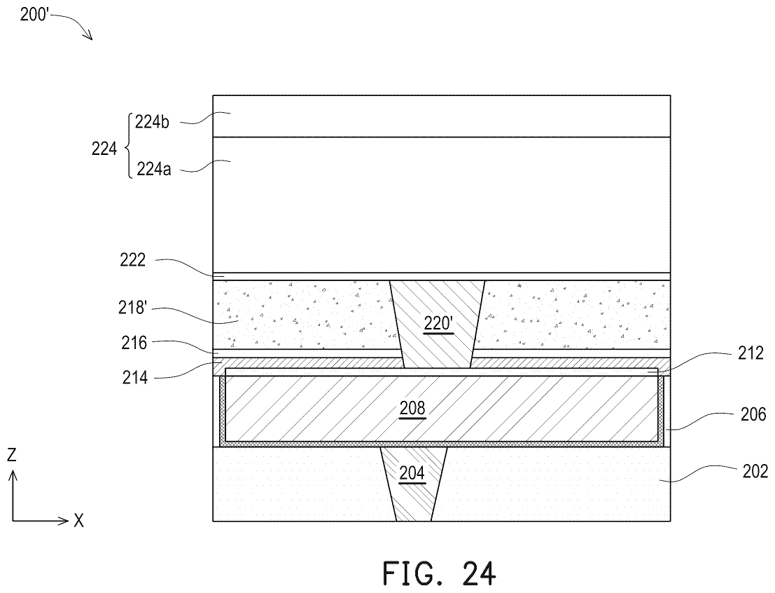

Referring to FIGS. 21 and 24, method 100′ includes a block 110′ where the third ESL 222 and the hard mask 224 are formed over the high-kappa dielectric material layer 218′. Operations at block 110′ are similar to those in block 110. For this reason, detailed description of operations at block 110′ is omitted for brevity.

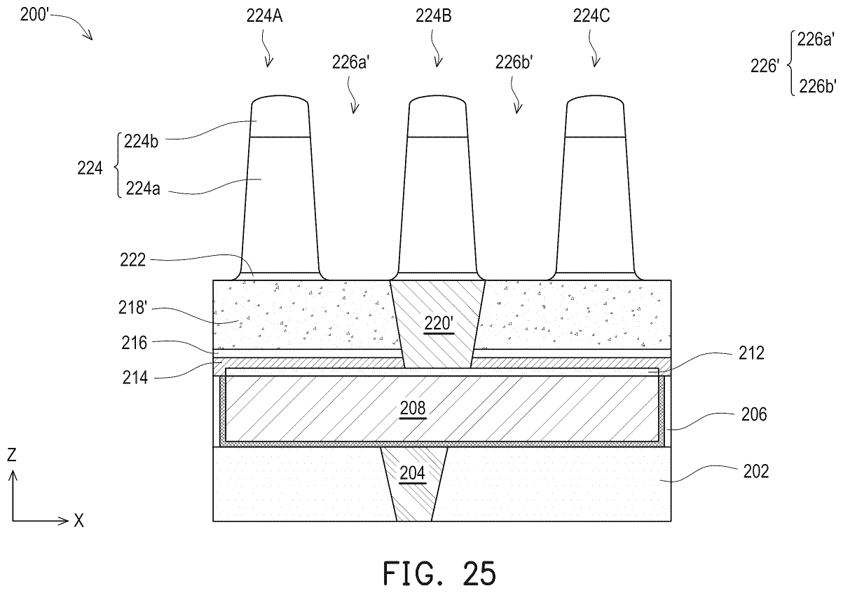

Referring to FIGS. 21 and 25, method 100 includes a block 112′ where the hard mask 224 and the third ESL 222 are patterned to form one or more openings (e.g., openings 226a′ and 226b′). Operations at block 112′ are similar to those in block 112. For this reason, detailed description of operations at block 112′ is omitted for brevity. However, in this present embodiment, etchant(s) used during the patterning of the hard mask 224 and the third ESL 222 would not substantially damage the high-kappa dielectric material layer 218′. That is, after the patterning of the hard mask 224 and the third ESL 222, the openings 226a′ and 226b′ do not extend into the high-kappa dielectric material layer 218′. The openings 226a′ and 226b′ may be individually or collectively referred to as opening(s) 226′.

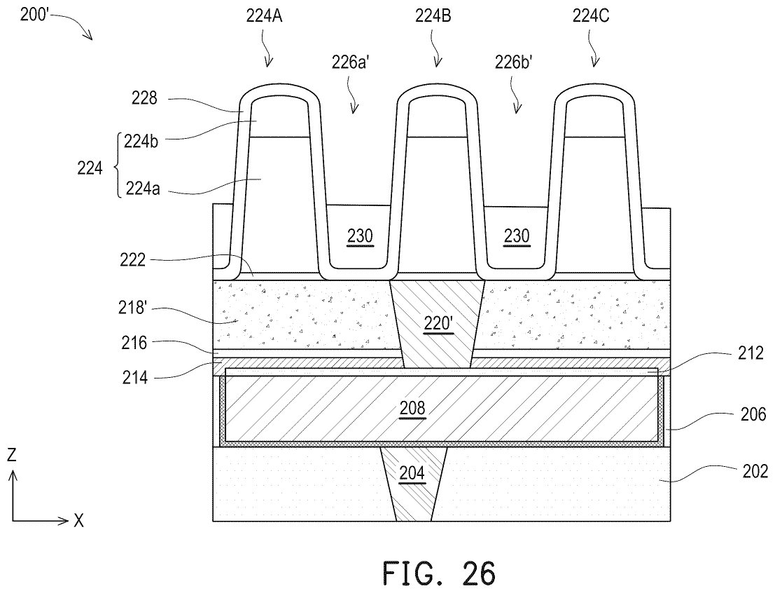

Referring to FIGS. 21 and 26, method 100′ includes the block 114 where the dielectric liner 228 is formed. Operations at block 114 have been described above with reference to FIG. 8 and repeated description is omitted for brevity.

Still referring to FIGS. 21 and 26, method 100′ includes the block 116 where the sacrificial layer 230 is formed over the dielectric liner 228 to partially fill the opening 226′. Operations at block 116 have been described above with reference to FIG. 8 and repeated description is omitted for brevity.

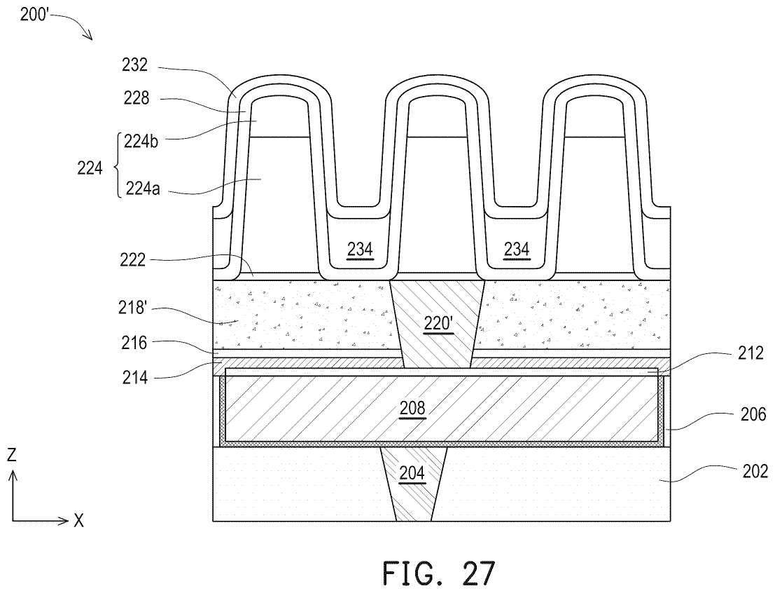

Referring to FIGS. 21 and 27, method 100′ includes the block 118 where the sustaining layer 232 is formed over the workpiece 200′. Operations at block 118 have been described above with reference to FIG. 9 and repeated description is omitted for brevity.

Still referring to FIGS. 21 and 27, method 100′ includes the block 120 where the sacrificial layer 230 is selectively removed to form the air gap 234 between the dielectric liner 228 and the sustaining layer 232. Operations at block 120 have been described above with reference to FIG. 9 and repeated description is omitted for brevity.

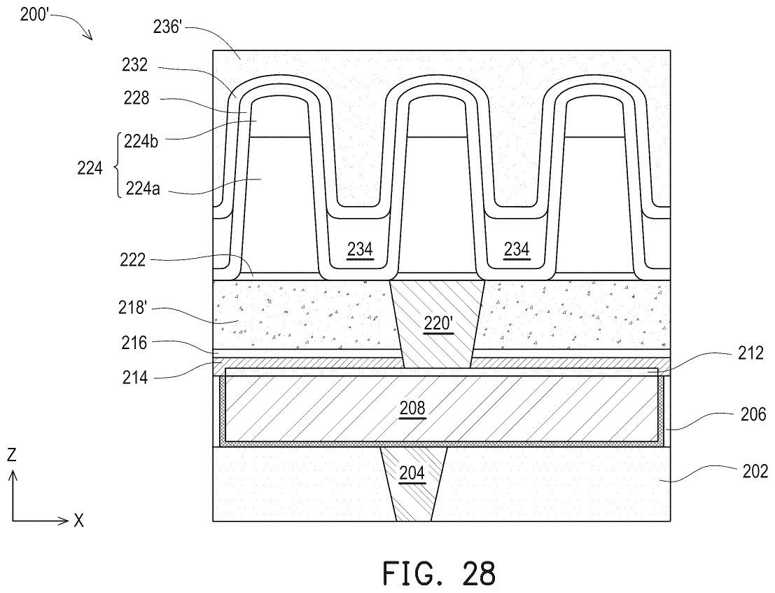

Referring to FIGS. 21 and 28, method 100′ includes a block 122′ where a low-k dielectric material layer 236′ is formed over the sustaining layer 232 using ALD, CVD, plasma enhanced CVD (PECVD), or microwave PECVD. The low-k dielectric material layer 236′ has a dielectric constant smaller than that of silicon oxide, which is about 3.9. For example, the low-k dielectric material layer 236′ may include a porous organosilicate thin film (e.g., SiOCH), tetraethylorthosilicate (TEOS) oxide, un-doped silicate glass, borophosphosilicate glass (BPSG), fluorosilicate glass (FSG), phosphosilicate glass (PSG), fluorine-doped silicon dioxide, carbon-doped silicon dioxide, porous silicon dioxide, porous carbon-doped silicon dioxide, silicon oxycarbonitride (SiOCN), boron carbonitride, spin-on silicon based polymeric dielectrics, or combinations thereof. In some embodiments, the sacrificial layer 230 may be selectively removed after forming the low-k dielectric material layer 236′. In another alternative embodiment, instead of forming the low-k dielectric material layer 236′ over the sustaining layer 232, the high-kappa dielectric material layer 236 may be formed over the sustaining layer 232 to further increase thermal dissipation.

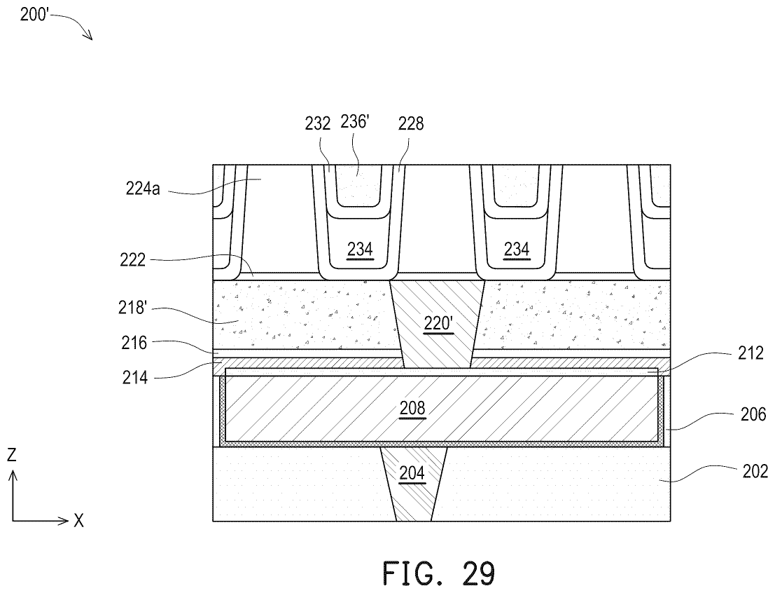

Referring to FIGS. 21 and 29, method 100′ includes the block 124 where the workpiece 200′ is planarized to expose the patterned hard mask 224. Operations at block 124 have been described above with reference to FIG. 11 and repeated description is omitted for brevity.

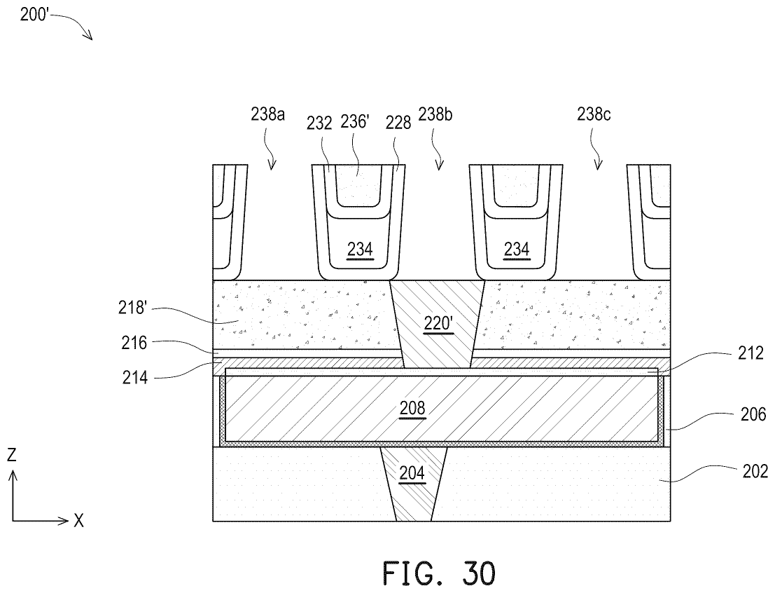

Referring to FIGS. 21 and 30, method 100′ includes the block 126 where the patterned hard mask layer 224 and the third ESL 222 are selectively removed to form openings 238a-238c. Operations at block 126 have been described above with reference to FIG. 12 and repeated description is omitted for brevity.

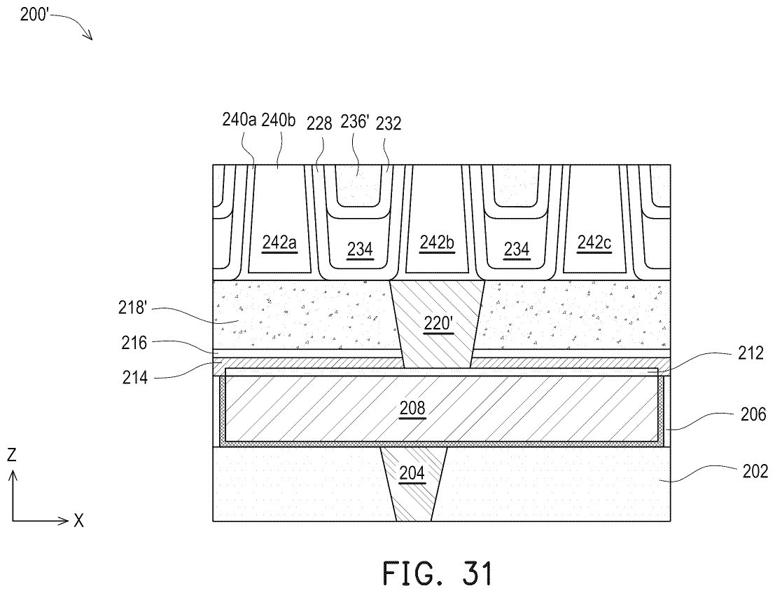

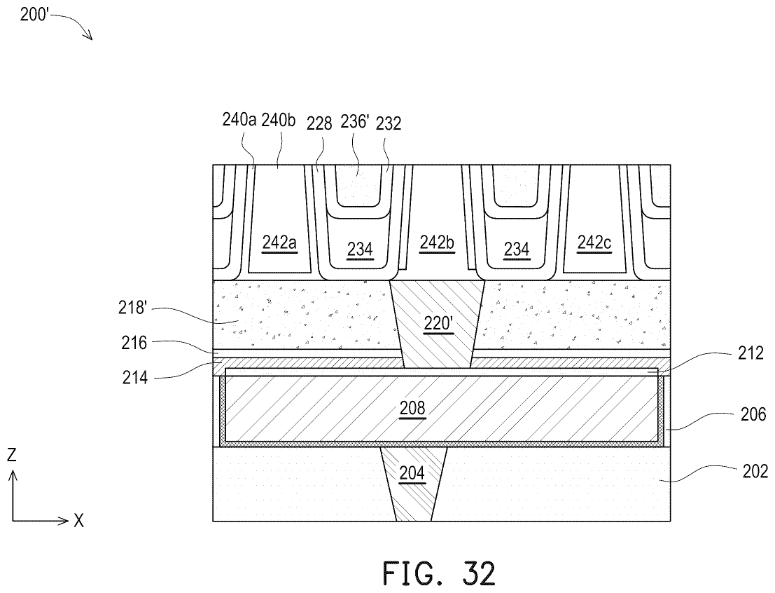

Referring to FIGS. 21 and 31, method 100 includes the block 128 where second conductive features 242a-242c are formed in the openings 238a-238c, respectively. Operations at block 128 have been described above with reference to FIGS. 13-15 and repeated description is omitted for brevity. In some other alternative embodiments, as represented by FIG. 32, the second conductive features 242a-242c may be formed in a way described with reference to FIGS. 17-20 and repeated description is omitted for brevity. In the fragmentary cross-sectional view illustrated by FIG. 32, the second conductive features 242a and 242c are in direct contact with the high-kappa dielectric material layer 218′, the metal fill layer 240b of the second conductive feature 242b is in direct contact with the via 220′.

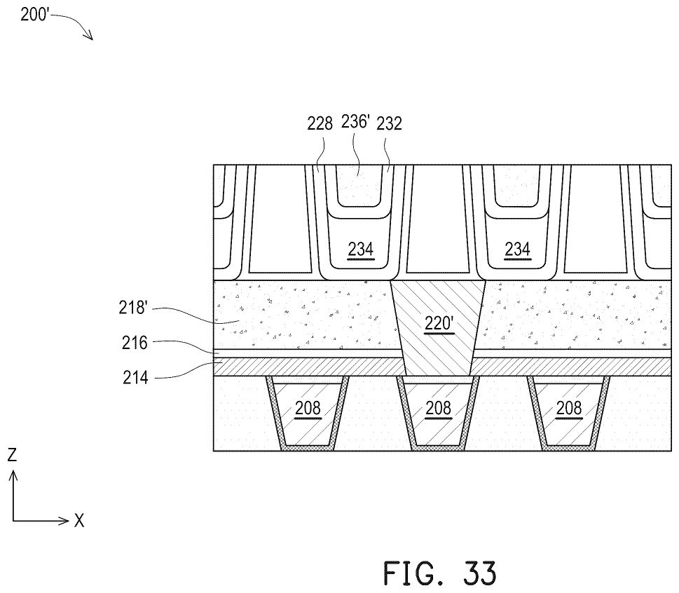

In the above embodiments, the first conductive feature 208 may be referred to as a metal line extending along the X direction. In some alternative embodiments, as depicted in FIG. 33, the first conductive feature 208 may be referred to as a via. For example, the first conductive feature 208 may be one of vias located at the CO level.

Although not intended to be limiting, one or more embodiments of the present disclosure provide many benefits to a semiconductor structure and the formation thereof. For example, the present disclosure provides a dielectric structure disposed between two adjacent conductive features and methods of forming the same. The dielectric structure includes a high-kappa dielectric material layer to facilitate heat dissipation. The dielectric structure also includes an air gap, thereby reducing the effective dielectric constant of the dielectric structure and parasitic capacitance of the semiconductor structure.

The present disclosure provides for many different embodiments. Semiconductor structures and methods of fabrication thereof are disclosed herein. In one exemplary aspect, the present disclosure is directed to a method. The method includes forming a first dielectric layer over a first conductive feature, forming a conductive via extending through the first dielectric layer and coupled to the first conductive feature, forming a hard mask layer over the conductive via, patterning the hard mask layer to form a first opening exposing the first dielectric layer, forming a sacrificial layer to partially fill the first opening, forming a porous dielectric layer on the sacrificial layer, after the forming of the porous dielectric layer, selectively removing the sacrificial layer to form an air gap, forming a second dielectric layer over the porous dielectric layer, and replacing a portion of the patterned hard mask layer disposed directly over the conductive via with a second conductive feature.

In some embodiments, the method may also include, before the forming of the sacrificial layer, conformally depositing a dielectric liner, wherein the air gap may be between the dielectric liner and the porous dielectric layer. In some embodiments, the first dielectric layer may include a low dielectric constant material layer. In some embodiments, the first opening may penetrate into the first dielectric layer. In some embodiments, the second dielectric layer may include a high thermal conductivity dielectric material layer. In some embodiments, the conductive via may be formed of Ru, Mo, or W. In some embodiments, the forming of the sacrificial layer may include depositing a polymer layer over the first dielectric layer, planarizing the polymer layer, and etching back the polymer layer. In some embodiments, the method may also include forming an etch stop layer between the first dielectric layer and the hard mask layer, wherein the patterning of the hard mask layer further patterns the etch stop layer, and wherein the replacing of the portion of the patterned hard mask layer with the second conductive feature may include performing a planarization process to expose the patterned hard mask layer, selectively removing the portion of the patterned hard mark layer and a portion of the etch stop layer thereunder to form a second opening, and forming the second conductive feature in the second opening. In some embodiments, the second conductive feature may include a barrier layer extending along sidewall and bottom surfaces of a metal fill layer. In some embodiments, the first dielectric layer may include a high thermal conductivity dielectric material layer, and the second dielectric layer may include a low dielectric constant material layer.

In another exemplary aspect, the present disclosure is directed to a method. The method includes forming a first dielectric layer over a substrate, patterning the first dielectric layer to form a trench separating the first dielectric layer into a first portion and a second portion, forming an insulation liner extending along sidewall surfaces of the first and second portions of the first dielectric layer, forming a capping structure between the first portion and second portion of the first dielectric layer to seal the trench to form an air gap, wherein the capping structure may include a dielectric liner extending along bottom and sidewall surfaces of a dielectric filler layer, wherein thermal conductivity of the dielectric filler is higher than thermal conductivity of the first dielectric layer, after the forming of the capping structure, selectively removing the first portion and the second portion of the first dielectric layer to form a first opening and a second opening, and forming a first conductive feature and a second conductive feature in the first opening and the second opening, respectively.

In some embodiments, the forming of the capping structure may include forming a polymer layer over the insulation liner to partially fill the trench, conformally depositing a first dielectric material layer over the polymer layer and the insulation liner, depositing a second dielectric material layer over the first dielectric material layer, selectively removing the polymer layer after the depositing of the first dielectric material layer to form the air gap, and performing a planarization process to remove parts of the patterned first dielectric layer, the first dielectric material layer, and the second dielectric material layer to form the capping structure. In some embodiments, the dielectric filler may include diamond or aluminum nitride. In some embodiments, the selectively removing of the polymer layer may include performing a thermal treatment. In some embodiments, the method may also include forming a conductive via embedded in a second dielectric layer and under the first dielectric layer, wherein the second opening exposes the conductive via, and the first opening exposes the second dielectric layer. In some embodiments, the forming of the first conductive feature and the second conductive feature may include after forming the first opening and the second opening, selectively forming a blocking layer on the conductive via, depositing a conductive barrier layer in the first opening and the second opening without being formed on the blocking layer, after the depositing of the conductive barrier layer, selectively removing the blocking layer, forming a metal layer on the conductive barrier layer, and removing portions of the metal layer and the conductive barrier layer over the capping structure. In some embodiments, the dielectric liner may include diamond or aluminum nitride.

In yet another exemplary aspect, the present disclosure is directed to a semiconductor structure. The semiconductor structure includes a conductive via extending through a first dielectric layer, a first conductive feature over and in direct contact with the conductive via, and a second conductive feature over the first dielectric layer and separated from the first conductive feature by a dielectric structure, wherein a top surface of the dielectric structure is coplanar with a top surface of the first conductive feature, and wherein the dielectric structure includes a bottom liner extending between the first and second conductive features and in direct contact with the first dielectric layer, a top liner extending between the first and second conductive features and in direct contact with the bottom liner, a second dielectric layer over the top liner, wherein the top liner extends along bottom and sidewall surfaces of the second dielectric layer, and an air gap confined by the bottom liner and the top liner.

In some embodiments, the second dielectric layer may include diamond or aluminum nitride (AlN), the first dielectric layer may include a low-k dielectric material. In some embodiments, the semiconductor structure may also include a third conductive feature embedded in a third dielectric layer and disposed under the first dielectric layer, and a metal cap disposed on the third conductive feature and in direct contact with both the third conductive feature and the first conductive feature, and the bottom liner may extend into third dielectric layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a first conductive feature extending through a first dielectric layer disposed over a plurality of transistors;
forming a first etch stop layer on the first dielectric layer;
forming a hard mask layer on the first etch stop layer;
forming a trench extending through the hard mask layer and the first etch stop layer,
depositing a second etch stop layer over the hard mask layer, wherein the second etch stop layer partially fills the trench, wherein a dielectric constant of the second etch stop layer is different from a dielectric constant of the first etch stop layer;
forming a sacrificial layer over the second etch stop layer and in a lower portion of the trench;
forming a seal layer on the sacrificial layer and in an upper portion of the trench;
after forming the seal layer, selectively removing the sacrificial layer to form an air gap in the lower portion of the trench; and
replacing remaining portions of the hard mask layer and the first etch stop layer with second conductive features, wherein one of the second conductive features is disposed on the first conductive feature.

2. The method of claim 1, wherein the forming of the seal layer comprises conformally depositing the seal layer.

3. The method of claim 2, further comprising:
after forming the seal layer, depositing a low-k dielectric material layer on the seal layer.

4. The method of claim 3, further comprising:
performing a planarization process to the low-k dielectric material layer, the seal layer, the hard mask layer, and the second etch stop layer.

5. The method of claim 1, wherein the first dielectric layer comprises a high-kappa dielectric material layer.

6. The method of claim 5, wherein the first dielectric layer comprises diamond, diamond-like carbon, or aluminum nitride (AlN).

7. The method of claim 1, wherein the replacing of the remaining portions of the hard mask layer and the first etch stop layer with the second conductive features comprises:
after forming the air gap in the lower portion of the trench, selectively removing the remaining portions of the hard mask layer and the first etch stop layer, thereby forming openings, wherein one of the openings exposes the first conductive feature; and
forming the second conductive features in the openings,
wherein the air gap is disposed between two adjacent conductive features of the second conductive features.

8. The method of claim 1, wherein the seal layer is a porous dielectric layer.

9. The method of claim 1, wherein the sacrificial layer comprises polyvinyl alcohol (PVA), polyacrylate or polycarbonate (PC).

10. A method, comprising:
forming a first interconnect layer comprising a first metal line disposed in a first dielectric layer;
forming a second interconnect layer comprising a via extending through a second dielectric layer, wherein the second dielectric layer is a high-kappa dielectric material layer;
depositing a hard mask layer over the second interconnect layer;
patterning the hard mask layer to form a first trench extending through the hard mask layer, wherein the first trench does not expose the via;
forming an isolation structure in the first trench, wherein the isolation structure comprises an air gap;
after the forming of the isolation structure, selectively removing the hard mask layer to form a second trench and a third trench, wherein the isolation structure is disposed between the second trench and the third trench; and
forming a second metal line and a third metal line in the second trench and the third trench, respectively, wherein the second metal line is electrically coupled to the first metal line by the via, and the second metal line is spaced apart from the third metal line by the isolation structure.

11. The method of claim 10, wherein the high-kappa dielectric material layer comprises diamond, diamond-like carbon, or aluminum nitride (AlN).

12. The method of claim 10, wherein the isolation structure comprises:
a first dielectric liner,
a second dielectric liner over the first dielectric liner;
an air gap disposed between the first dielectric liner and the second dielectric liner; and
a dielectric filler, wherein the second dielectric liner extends along sidewalls and a bottom surface of the dielectric filler.

13. The method of claim 12, wherein the first dielectric liner and the second dielectric liner comprise different compositions.

14. The method of claim 12, wherein the second dielectric liner is porous.

15. The method of claim 12, wherein the dielectric filler comprises a low-k dielectric material layer.

16. The method of claim 10, wherein top surfaces of the second and third metal lines are coplanar with a top surface of the isolation structure.

17. A method, comprising:
receiving a precursor structure comprising:
a plurality of transistors over a substrate, and
an interconnect layer over the plurality of transistors, wherein the interconnect layer comprises a first metal line disposed in a first dielectric layer, wherein the first metal line extends lengthwise along a first direction;
forming a dielectric layer over the interconnect layer;
removing a portion of the dielectric layer to form a trench extending through the dielectric layer;
conformally depositing a dielectric liner over the dielectric layer and in the trench;
forming a dielectric structure on the dielectric liner to fill an upper portion of the trench, wherein an air gap is enclosed by the dielectric liner and the dielectric structure;
planarizing the dielectric structure, the dielectric liner, and the dielectric layer, thereby exposing a top surface of the dielectric layer;
after the planarizing, selectively removing remaining portions of the dielectric layer without substantially etching the dielectric structure to form a first opening and a second opening, wherein the first opening and the second opening are separated by the dielectric liner and the dielectric structure; and
forming a second metal line and a third metal line the first opening and the second opening, respectively, wherein the second metal line and third metal line extend lengthwise along a second direction different from the first direction.

18. The method of claim 17, wherein the forming of the dielectric structure comprises:
after the conformally depositing of the dielectric liner, forming a sacrificial layer in a lower portion of the trench;
conformally depositing a porous dielectric layer on the dielectric liner and the sacrificial layer;
after the conformally depositing of the porous dielectric layer, selectively removing the sacrificial layer to form the air gap; and
forming a low-k dielectric layer on the porous dielectric layer.

19. The method of claim 18, wherein the sacrificial layer comprises polymer.

20. The method of claim 17, further comprising:
forming a via disposed in a high-kappa dielectric material layer, wherein the via is disposed between and electrically connects the first metal line and the second metal line.
